(19) United States
(12) Patent Application Publication
(10) Pub. No.: US 2018/0319944 A1
(43) Pub. Date: Nov. 8, 2018

(54) MULTILAYER CONSTRUCTION INCLUDING BARRIER LAYER AND SEALING LAYER

(71) Applicant: 3M INNOVATIVE PROPERTIES COMPANY, St. Paul, MN (US)

(72) Inventors: Xue-hua Chen, Shanghai (CN); Jitendra S. Rathore, Woodbury, MN (US); Weigang Lin, Jiansu Province (CN); Yongjie Li, Shanghai (CN); Liya Cao, Shanghai (CN); Sonja S. Mackey, St. Paul, MN (US); Moses M. David, Woodbury, MN (US); Christopher S. Lyons, St. Paul, MN (US); Richard J. Pokorny, Maplewood, MN (US); Paul B. Armstrong, Minneapolis, MN (US); Zai-Ming Qiu, Woodbury, MN (US); Zuetao Yu, Shanghai (CN)

(21) Appl. No.: 15/775,457

(22) PCT Filed: Nov. 8, 2016
(86) PCT No.: PCT/US2016/060950

§ 371 Date: May 11, 2018

Related U.S. Application Data
(60) Provisional application No. 62/297,225, filed on Feb. 19, 2016.
(60) Provisional application No. 62/253,785, filed on Nov. 11, 2015.

(51) Int. Cl. C08J 7/04; C09D 143/04

(52) U.S. Cl. CPC C08J 7/045; C09D 143/04; H01L 31/0481; C08J 2443/04; C08J 2367/02

(57) ABSTRACT

Multilayer constructions are provided, for instance including a barrier layer, a sealing layer, and a polymer layer. The barrier layer has a major surface on which the sealing layer is disposed, and the sealing layer includes crosslinked silsesquioxane. The polymer layer includes a crosslinked polymer, and is disposed adjacent to a major surface of the barrier layer opposite from the sealing layer. The multilayer construction may further include additional layers, such as a substrate. Devices are also provided including the multilayer constructions.

### TECHNICAL FIELD

The present disclosure relates to multilayer constructions having a barrier layer as well as a sealing layer. The present disclosure further relates to devices containing the multilayer constructions.

### BACKGROUND

Multilayer constructions including a barrier layer decrease the passage of one or more gases and/or liquids through the construction. Some typical barrier layer materials include, for instance, metals, metal oxides, and diamond-like glass. However, the presence of defects in such barrier layers negatively affects the barrier performance of the barrier layer. A need therefore exists to counter the effects of defects in barrier layers.

### SUMMARY

The present disclosure provides multilayer constructions designed to mitigate one or more problems associated with defects present in a barrier layer.

In a first aspect, the present disclosure provides a multilayer construction. The multilayer construction includes a barrier layer having a major surface, a sealing layer including crosslinked silsesquioxane disposed on the major surface of the barrier layer, and a polymer layer including a crosslinked polymer disposed adjacent to a major surface of the barrier layer opposite from the sealing layer.

In a second aspect, the present disclosure provides another multilayer construction. The multilayer construction includes a barrier layer having a major surface and a sealing layer including crosslinked silsesquioxane disposed on the major surface of the barrier layer. The multilayer construction further includes a substrate disposed adjacent to a major surface of the barrier layer opposite from the sealing layer, and a polymer layer including a crosslinked polymer disposed between the barrier layer and the substrate.

In a third aspect, the present disclosure provides a device. The device includes the multilayer construction according to the first or second aspect. Further, the device is usually selected from a light generating device, a display, a solar cell, or a vacuum insulation panel.

Various unexpected results and advantages are obtained in exemplary embodiments of the disclosure. One such advantage of exemplary embodiments of the present disclosure is that defects in a barrier layer are sealed, providing a multilayer construction having better barrier characteristics than without the sealing layer.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE DRAWINGS

The disclosure may be more completely understood in consideration of the following detailed description of various embodiments of the disclosure in connection with the accompanying figures, in which:

FIG. 1 is a cross-sectional schematic of an exemplary two-layer multilayer construction.

FIG. 2 is a cross-sectional schematic of an exemplary three-layer multilayer construction.

FIG. 3 is a cross-sectional schematic of an exemplary four-layer multilayer construction.

FIG. 4 is a cross-sectional schematic of an exemplary five-layer multilayer construction.

FIG. 5 is a cross-sectional schematic of an exemplary six-layer multilayer construction.

FIG. 6 is a cross-sectional schematic of another exemplary three-layer multilayer construction.

FIG. 7 is a cross-sectional schematic of an exemplary device including a two-layer multilayer construction on a multilayered device.

While the above-identified drawings, which may not be drawn to scale, set forth embodiments of the present disclosure, other embodiments are also contemplated, as noted in the Detailed Description.

### DETAILED DESCRIPTION

Functional silsesquioxanes (SSQs) include a polyhedral cluster having the generic formula (RSiO_{1.5})n obtained from hydrolytic condensation of trialkoxy silanes and having functional units such as unsaturated carbon-carbon bonds (e.g., a vinyl, an allyl, an acrylate), a mercapto group, or an epoxy group. These functional groups make SSQs curable, such as by thermal curing, UV radiation, and/or electron-beam radiation. SSQ has been reported to be used in adhesives as a cross-linker or viscosity reducer, and in coatings to increase coating hardness, heat resistance, weather resistance, flame retardant and impact resistance, as well as to reduce coating thermal expansion.

The present disclosure provides a multilayer construction with a sealing layer, a barrier layer, and a polymer layer. The sealing layer is an organic/inorganic hybrid composition composed of functional SSQs (or functional SSQs and silica nanoparticles), which is crosslinked by UV radiation. The sealing layer advantageously can not only protect the barrier layer, but also significantly improve the moisture barrier performance of the barrier layer, such as to a water vapor transmission rate of 0.005 grams/m²-day or less at 50° C. and 100% relative humidity.

For the following Glossary of defined terms, these definitions shall be applied for the entire application, unless a different definition is provided elsewhere in the specification.

### Glossary

Certain terms are used throughout the present disclosure that, while for the most part are well known, may require some explanation. It should be understood that, as used herein:

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

The terms “comprises” and variations thereof do not have a limiting meaning where these terms appear in the description and claims.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

The term “layer” refers to a coating composition that has been applied onto a major surface of a substrate or onto another layer on a substrate, and refers to the components remaining after a drying and/or curing process.

The term “adjacent” in reference to a first layer being adjacent to a second layer, means that the first layer can contact the second layer or can be separated from the second layer by one or more intermediary layers.

The term “polymer” refers to homopolymers and copolymers, as well as homopolymers or copolymers that may be formed in a miscible blend, e.g., by coextrusion or by reaction, including, e.g., transesterification. The term “polymer” also includes plasma deposited polymers.

The term “copolymer” includes both random and block copolymers.

The term “curable polymer” includes both crosslinked and uncrosslinked polymers.

The term “crosslinked” polymer refers to a polymer whose polymer chains are joined together by covalent chemical bonds, usually via crosslinking molecules or groups, to form a network polymer. A crosslinked polymer is generally characterized by insolubility, but may be swellable in the presence of an appropriate solvent.

The term “visible light-transmissive” support, layer, assembly or device means that the support, layer, assembly or device has an average transmission over the visible portion of the spectrum, Tᵥᵢₛ, of at least about 20%, measured along the normal axis.

The term “diamond-like glass” (DLG) refers to substantially or completely amorphous glass including carbon and silicon, and optionally including one or more additional components selected from the group including hydrogen, nitrogen, oxygen, fluorine, sulfur, titanium, and copper. Other elements may be present in certain embodiments. The amorphous diamond-like glass films may contain clustering of atoms to give it a short-range order but are essentially void of medium and long range ordering that lead to micro or macro crystallinity which can adversely scatter radiation having wavelengths of from 180 nanometers (nm) to 800 nm.

As used herein, the term “organic group” means a hydrocarbon group (with optional elements other than carbon and hydrogen, such as oxygen, nitrogen, sulfur, silicon, and halogens) that is classified as an aliphatic group, cyclic group, or combination of aliphatic and cyclic groups (e.g., alkaryl and aralkyl groups). In the context of the present invention, the organic groups are those that do not interfere with the formation of curable silsesquioxane polymer. The term “aliphatic group” means a saturated or unsaturated linear or branched hydrocarbon group. This term is used to encompass alkyl, alkenyl, and alkynyl groups, for example. The term “alkyl group” is defined herein below. The term “alkenyl group” means an unsaturated, linear or branched hydrocarbon group with one or more carbon-carbon double bonds, such as a vinyl group. The term “alkynyl group” means an unsaturated, linear or branched hydrocarbon group with one or more carbon-carbon triple bonds. The term “cyclic group” means a closed ring hydrocarbon group that is classified as an alicyclic group, aromatic group, or heterocyclic group. The term “alicyclic group” means a cyclic hydrocarbon group having properties resembling those of aliphatic groups. The term “aromatic group” or “aryl group” are defined herein below. The term “heterocyclic group” means a closed ring hydrocarbon in which one or more of the atoms in the ring is an element other than carbon (e.g., nitrogen, oxygen, sulfur, etc.). The organic group can have any suitable valency but is often monovalent or divalent.

The term “alkyl” refers to a monovalent group that is a radical of an alkane and includes straight-chain, branched, cyclic, and bicyclic alkyl groups, and combinations thereof, including both unsubstituted and substituted alkyl groups. Unless otherwise indicated, the alkyl groups typically contain from 1 to 30 carbon atoms. In some embodiments, the alkyl groups contain 1 to 20 carbon atoms, 1 to 10 carbon atoms, 1 to 6 carbon atoms, 1 to 4 carbon atoms, or 1 to 3 carbon atoms. Examples of alkyl groups include, but are not limited to, methyl, ethyl, n-propyl, n-butyl, n-pentyl, isobutyl, t-butyl, isopropyl, n-octyl, n-heptyl, ethylhexyl, cyclopentyl, cyclohexyl, cycloheptyl, adamantyl, norbornyl, and the like.

The term “alkylene” refers to a divalent group that is a radical of an alkane and includes groups that are linear, branched, cyclic, bicyclic, or a combination thereof. Unless otherwise indicated, the alkylene group typically has 1 to 30 carbon atoms. In some embodiments, the alkylene group has 1 to 20 carbon atoms, 1 to 10 carbon atoms, 1 to 6 carbon atoms, or 1 to 4 carbon atoms. Examples of alkylene groups include, but are not limited to, methylene, ethylene, 1,3-propylene, 1,2-propylene, 1,4-butylene, 1,4-cyclohexylene, and 1,4-cyclohexyldimethylene.

The term “alkoxy” refers to a monovalent group having an oxy group bonded directly to an alkyl group.

The term “aryl” refers to a monovalent group that is aromatic and, optionally, carbocyclic. The aryl has at least one aromatic ring. Any additional rings can be unsaturated, partially saturated, saturated, or aromatic. Optionally, the aromatic ring can have one or more additional carbocyclic rings that are fused to the aromatic ring. Unless otherwise indicated, the aryl groups typically contain from 6 to 30 carbon atoms. In some embodiments, the aryl groups contain 6 to 20, 6 to 18, 6 to 16, 6 to 12, or 6 to 10 carbon atoms. Examples of an aryl group include phenyl, naphthyl, biphenyl, phenanthryl, and anthracyl.

The term “arylene” refers to a divalent group that is aromatic and, optionally, carbocyclic. The arylene has at least one aromatic ring. Any additional rings can be unsaturated, partially saturated, or saturated. Optionally, an aromatic ring can have one or more additional carbocyclic rings that are fused to the aromatic ring. Unless otherwise indicated, arylene groups often have 6 to 20 carbon atoms, 6 to 18 carbon atoms, 6 to 16 carbon atoms, 6 to 12 carbon atoms, or 6 to 10 carbon atoms.

The term “aralkyl” refers to a monovalent group that is an alkyl group substituted with an aryl group (e.g., as in a benzyl group). The term “alkaryl” refers to a monovalent group that is an aryl substituted with an alkyl group (e.g., as in a tolyl group). Unless otherwise indicated, for both groups, the alkyl portion often has 1 to 10 carbon atoms, 1 to 6 carbon atoms, or 1 to 4 carbon atoms and an aryl portion often has 6 to 20 carbon atoms, 6 to 18 carbon atoms, 6 to 16 carbon atoms, 6 to 12 carbon atoms, or 6 to 10 carbon atoms.

The term “aralkylene” refers to a divalent group that is an alkylene group substituted with an aryl group or an alkylene group attached to an arylene group. The term “alkarylene” refers to a divalent group that is an arylene group substituted with an alkyl group or an arylene group attached to an alkylene group. Unless otherwise indicated, for both groups, the alkyl or alkylene portion typically has from 1 to 20 carbon atoms, 1 to 10 carbon atoms, 1 to 6 carbon atoms, or 1 to 4 carbon atoms. Unless otherwise indicated, for both groups, the aryl or arylene portion typically has from 6 to 20 carbon atoms, 6 to 18 carbon atoms, 6 to 16 carbon atoms, 6 to 12 carbon atoms, or 6 to 10 carbon atoms.

The term “hydrolyzable group” refers to a group that can react with water having a pH of 1 to 10 under conditions of atmospheric pressure. The hydrolyzable group is often converted to a hydroxyl group when it reacts. The hydroxyl group often undergoes further reactions. Typical hydrolyzable groups include, but are not limited to, alkoxy, aryloxy, aralkyloxy, alkaryloxy, acyloxy, or halo. As used herein, the term is often used in reference to one of more groups bonded to a silicon atom in a silyl group.

The term “alkoxy” refers to a monovalent group having an oxy group bonded directly to an alkyl group.

The term “aryloxy” refers to a monovalent group having an oxy group bonded directly to an aryl group.

The terms “aralkyloxy” and “alkaryloxy” refer to a monovalent group having an oxy group bonded directly to an aralkyl group or an alkaryl group, respectively.

The term “acyloxy” refers to a monovalent group of the formula —O(CO)R^{b} where R^{b} is alkyl, aryl, aralkyl, or alkaryl. Suitable alkyl R^{b} groups often have 1 to 10 carbon atoms, 1 to 6 carbon atoms, or 1 to 4 carbon atoms. Suitable aryl R^{b} groups often have 6 to 12 carbon atoms such as, for example, phenyl. Suitable aralkyl and alkaryl R^{b} groups often have an alkyl group with 1 to 10 carbon atoms, 1 to 6 carbon atoms, or 1 to 4 carbon atoms and an aryl having 6 to 12 carbon atoms.

The term “halo” refers to a halogen atom such as fluoro, bromo, iodo, or chloro. When part of a reactive silyl, the halo group is often chloro.

The term “(meth)acryloyloxy group” includes an acryloyloxy group (—O—(CO)—CH═CH₂) and a methacryloyloxy group (—O—(CO)—C(CH₃)═CH₂).

The term “(meth)acryloylamino group” includes an acryloylamino group (—NR—(CO)—CH═CH₂) and a methacryloylamino group (—NR—(CO)—C(CH₃)═CH₂) including embodiments wherein the amide nitrogen is bonded to a hydrogen, methyl group, or ethyl group (R is H, methyl, or ethyl).

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment,” “in many embodiments” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

Various exemplary embodiments of the disclosure will now be described. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

In a first aspect, the present disclosure provides a multilayer construction including a barrier layer having a major surface, a sealing layer comprising crosslinked silsesquioxane disposed on the major surface of the barrier layer, and a polymer layer. The polymer layer includes a crosslinked polymer, and is disposed adjacent to a major surface of the barrier layer opposite from the sealing layer.

In a second aspect, the present disclosure provides another multilayer construction. The multilayer construction includes a barrier layer having a major surface and a sealing layer including crosslinked silsesquioxane disposed on the major surface of the barrier layer. The multilayer construction further includes a substrate disposed adjacent to a major surface of the barrier layer opposite from the sealing layer, and a polymer layer including a crosslinked polymer disposed between the barrier layer and the substrate.

The below disclosure relates to both the first aspect and the second aspect.

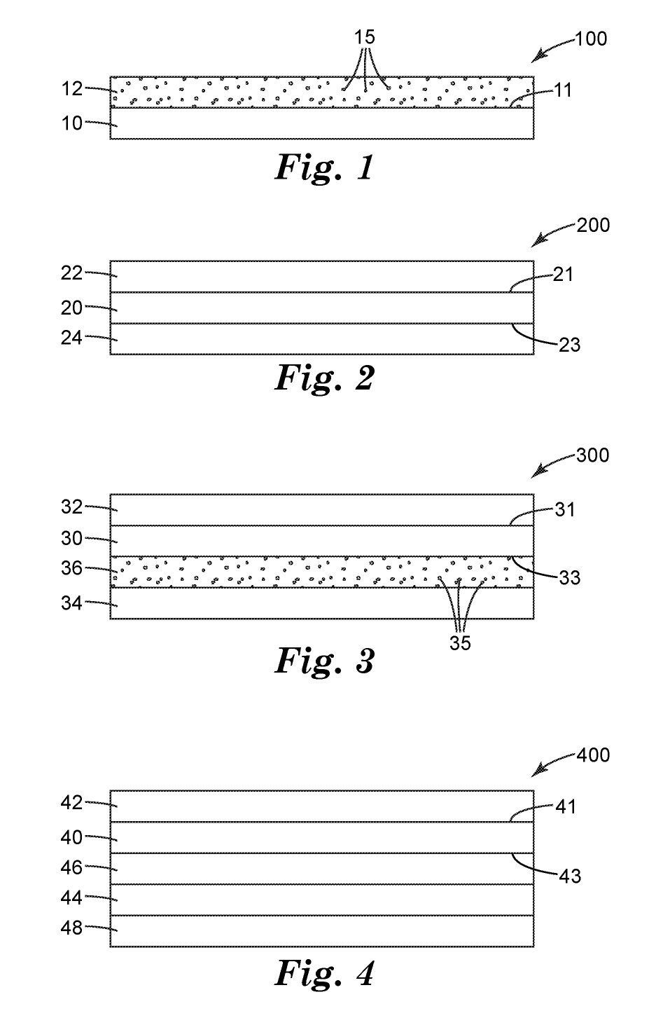

Referring to FIG. 1, a multilayer construction 100 is provided including a barrier layer 10 having a major surface 11 and a sealing layer 12 comprising crosslinked silsesquioxane disposed on the major surface 11 of the barrier layer 10. In certain embodiments, the barrier layer is a film, for instance a film having a thickness of less than 2 microns, or less than 1 micron, or less than 800 nanometers, or less than 700 nanometers, such as greater than 4 nanometers but less than 1 micron thick.

The barrier layer is not particularly limited as long as it blocks the passage of at least some of a vapor, gas, or liquid. The barrier layer is often selected from a layer of: a metal, a metal oxide, a mixture of metals, a mixture of metal oxides, a metal nitride, a metal carbide, a metal oxynitride, a metal oxycarbide, a mixture of metal carbides, a mixture of metal nitrides, a mixture of metal oxycarbides, a mixture of metal oxynitrides, or a combination thereof. For example and without limitation, the barrier layer may be a layer of: aluminum, indium, germanium, tin, antimony, bismuth, aluminosilicate, alumina, zirconia, titania, silica, SiₓO_{y}N_{z}, SiON, silicon nitride, SiₓAl_{y}O_{z}, diamond-like glass (DLG) or SiO_{y}C_{z}. The formation of DLG layers, and their properties, are disclosed in U.S. Pat. No. 6,696,157 (David et al.). In many embodiments the barrier layer is inorganic. In contrast, in certain embodiments the barrier layer includes organic materials.

In most embodiments, the crosslinked silsesquioxane is formed from functionalized silsesquioxanes comprising acrylate groups, vinyl groups, mercapto groups, epoxy groups, or a combination thereof. The functionalized silsesquioxanes, (RSiO_{3/2})ₙ, are typically made from R—SiXYZ via known sol-gel processes, wherein each of X, Y, and Z is a hydrolysable group (such as alkoxy groups). The functional groups allow for crosslinking of the silsesquioxane clusters during exposure to radiation to form polymers such as polyacrylate from acrylate groups, poly(thiolene) from mercapto-vinyl groups, mercapto-allyl groups, mercapto-acrylate groups, and/or polyether from epoxy groups. Multilayer constructions according to the present disclosure provide greater barrier properties (including to moisture vapor) than provided by the barrier layer alone.

In certain embodiments, a curable silsesquioxane polymer includes a three-dimensional branched network having the following formula:

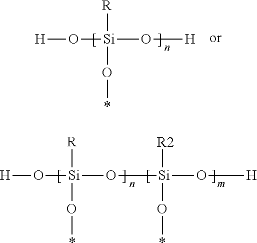

wherein: the oxygen atom at the * is bonded to another Si atom within the three-dimensional branched network; R is an organic group comprising an ethylenically unsaturated group; R2 is an organic group that is not an ethylenically unsaturated group; n or n+m is an integer of greater than 3; and the —OH groups are present in an amount of at least 15 wt-% of the polymer.

In one embodiment, a curable silsesquioxane polymer includes a three-dimensional branched network which is a condensation reaction product of a compound having the formula Z—Y—Si(R¹)₃, wherein: Y is a bond, an alkylene group, an arylene group, or a combination thereof; Z is an ethylenically unsaturated group selected from a vinyl group, a vinylether group, a (meth)acryloyloxy group, and a (meth)acryloylamino group; and each R¹ group is independently a hydrolyzable group; wherein the polymer includes —OH groups in an amount of at least 15 wt-% of the polymer.

In certain embodiments, a curable silsesquioxane polymer includes a three-dimensional branched network having the following formula:

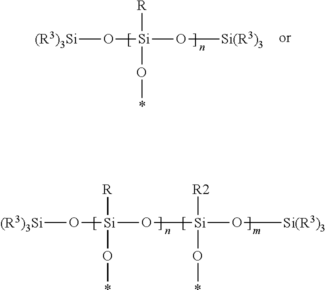

wherein: the oxygen atom at the * is bonded to another Si atom within the three-dimensional branched network; R is an organic group comprising an ethylenically unsaturated group; R2 is an organic group that is not an ethylenically unsaturated group; R3 is a non-hydrolyzable group; and n or n+m is an integer of greater than 3.

In one embodiment, a curable silsesquioxane polymer includes a three-dimensional branched network which is a reaction product of a compound having the formula Z—Y—Si(R¹)₃, wherein Y is a bond or a divalent group selected from alkylene, arylene, alkarylene, and araalkylene; Z is an ethylenically unsaturated group selected from a vinyl group, a vinylether group, a (meth)acryloyloxy group, and a (meth)acryloylamino group; and each R¹ group is independently a hydrolyzable group; wherein the reaction product of the hydrolyzable group has been converted to OSi(R³)₃ wherein R³ is a non-hydrolyzable group. In certain embodiments, a curable silsesquioxane polymer includes a three-dimensional branched network which is a condensation reaction product of a compound having the formula Z—Y—Si(R¹)₃ as just described and a compound having the formula X—Y—Si(R¹)₃, wherein each R¹ group and Y is the same as just described and X is hydrogen, a group selected from alkyl, aryl, aralkyl, alkyaryl, or a reactive group that is not an ethylenically unsaturated group, or a combination thereof. The alky group can optionally comprise (e.g. halogen) substituents, such as in the case of fluoroalkyl.

In some embodiments, the silsesquioxane polymer is free of hydrolyzed groups such as —OH group. In other embodiments, the silsesquioxane polymer further comprises hydrolyzed groups, typically in an amount no greater than 5 wt-%.

In a typical photopolymerization method to crosslink the functionalized silsesquioxanes, a mixture may be irradiated with ultraviolet (UV) rays in the presence of a photopolymerization initiator (i.e., photoinitiators). Preferred photoinitiators for unsaturated carbon-carbon bonds are those available under the trade designations LUCIRIN from BASF Corporation, (Florham Park, N.J.), IRGACURE and DAROCUR from Ciba Specialty Chemical Corp., (Tarrytown, N.Y.) and include 1-hydroxy cyclohexyl phenyl ketone (IRGACURE 184), 2,2-dimethoxy-1,2-diphenylethan-1-one (IRGACURE 651), bis(2,4,6-trimethylbenzoyl)phenylphosphineoxide (IRGACURE 819), 1-[4-(2-hydroxyethoxy)phenyl]-2-hydroxy-2-methyl-1-propane-1-one (IRGACURE 2959), 2-benzyl-2-dimethylamino-1-(4-morpholinophenyl)butanone (IRGACURE 369), 2-methyl-1-[4-(methylthio)phenyl]-2-morpholinopropan-1-one (IRGACURE 907), 2-hydroxy-2-methyl-1-phenyl propan-1-one (DAROCUR 1173), and 2,4,6-trimethylbenzoyldiphenyl phosphine oxide (LUCIRIN TPO). Particularly preferred photoinitiators are IRGACURE 819, 651, 184 and 2959, and LUCIRIN TPO.

Photoinitiators for epoxy groups include photo-acid generators (PAG) or photo-base generators. Useful cationic initiators include the aromatic onium salts, including salts of Group Va elements, such as phosphonium salts, for example, triphenyl phenacylphosphonium hexafluorophosphate; salts of Group VIa elements, such as sulfonium salts, for example, triphenylsulfonium tetrafluoroborate, triphenylsulfonium hexafluorophosphate and triphenylsulfonium hexafluoroantimonate; and salts of Group VIIa elements, such as iodonium salts such as diphenyliodonium chloride and diaryl iodonium hexafluoroantimonate, the latter being preferred. The aromatic onium salts and their use as cationic initiators in the polymerization of epoxy compounds are described in detail in U.S. Pat. No. 4,058,401, “Photocurable Compositions Containing Group VIA Aromatic Onium Salts,” by J. V. Crivello issued Nov. 15, 1977; U.S. Pat. No. 4,069,055, “Photocurable Epoxy Compositions Containing Group VA Onium Salts,” by J. V. Crivello issued Jan. 17, 1978, U.S. Pat. No. 4,101,513, “Catalyst For Condensation Of Hydrolyzable Silanes And Storage Stable Compositions Thereof,” by F. J. Fox et al. issued Jul. 18, 1978; and U.S. Pat. No. 4,161,478, “Photoinitiators,” by J. V. Crivello issued Jul. 17, 1979, the disclosures of which are incorporated herein by reference.

Useful cationic photoiniators include diaryliodonium salts, triarylsulfonium salts, benzylsulfonium salts, phenacylsulfonium salts, N-benzylpyridinium salts, N-benzylpyrazinium salts, N-benzylammonium salts, phosphonium salts, hydrazinium salts, and ammonium borate salts.

Other cationic initiators can also be used in addition to those referred to above; for example, the phenyldiazonium hexafluorophosphates containing alkoxy or benzyloxy radicals as substituents on the phenyl radical as described in U.S. Pat. No. 4,000,115, “Photopolymerization Of Epoxides,” by Sanford S. Jacobs issued Dec. 28, 1976, the disclosure of which is incorporated herein by reference. Preferred cationic initiators for use in the compositions of this invention are the salts of Group VIa elements and especially the sulfonium salts; and also the Group VIIa elements, particularly the diaryl iodonium hexaflurorantimonates. Particular cationic catalysts include diphenyl iodonium salts of tetrafluoro borate, hexafluoro phosphate, hexafluoro arsenate, and hexafluoro antimonate; and triphenyl sulfonium salts of tetrafluoroborate, hexafluoro phosphate, hexafluoro arsenate, and hexafluoro antimonate.

CYRACURE UVI-6976 (a mixture of triarylsulfonium hexafluoroantimonate salts in propylene carbonate) and UVI-6992 are examples of cationic photoinitiators available from Dow Chemical (Midland, Mich.). DAROCUR 1173 cationic photoinitator can be obtained from Ciba Specialty Chemical Corp. (Tarrytown, N.Y.).

Cationic initiator is typically present in the compositions of the invention in a range from about 1% to about 5% by weight.

In another embodiments, the crosslinked silsesquioxane can be formed directly from R—SiXYZ under photo-irradiation in the presence of photo-radical initiator for curing of functionalized R group (e.g. unsaturated carbon-carbon-bonds) and photo-acid generator initiator for curing of the —SiXYZ group to silsesquioxane simultaneously.

The sealing layer can be applied to the barrier layer using conventional coating methods such as roll coating (e.g., gravure roll coating), die coating (e.g., slot die coating), or spray coating (e.g., electrostatic spray coating), then crosslinked using, for example, UV radiation. Suitable wet coating thickness of the sealing layer is between about 1 micron and 25 microns, inclusive. Upon curing (and optionally drying), typically the thickness of the sealing layer is between _1 micron and 10 microns.

In certain embodiments, the barrier layer is self-supporting, such that the multilayer construction includes just the barrier layer and the sealing layer and no additional structure is required to support the barrier layer and sealing layer. Such a multilayer construction can be prepared, for example, by forming a barrier layer on a liner, forming a sealing layer on the barrier layer, and then removing the liner to leave the two-layer multilayer construction.

Referring again to FIG. 1, in certain embodiments, the sealing layer 12 further comprises a plurality of inorganic nanoparticles 15 Such inorganic nanoparticles may include, for example and without limitation, metal nanoparticles, metal oxide nanoparticles, mixed metal oxide nanoparticles, or a combination thereof, for example silica nanoparticles, zirconia nanoparticles, alumina nanoparticles, titania nanoparticles, Indium doped tin oxide (ITO) nanoparticles, antimony doped tin oxide (ATO) nanoparticles, or a combination thereof. Moreover, the plurality of inorganic nanoparticles are optionally functionalized with acrylate groups, vinyl groups, mercapto groups, epoxy groups, or a combination thereof. Functionalization of the inorganic nanoparticles allows for greater interaction between the nanoparticles and the SSQs during crosslinking. When included, inorganic nanoparticles generally provide enhanced mechanical strength (e.g., durability) to the sealing layer. Suitable amounts of inorganic nanoparticles in the sealing layer include between 0 percent by weight and 95 percent by weight (dry particles of the total dry sealing layer). Preferred is between 5 percent by weight and 95 percent by weight; more preferred is between 10 percent by weight and 90 percent by weight; more preferred is between 20 percent by weight and 80 percent by weight; more preferred is between 30 percent by weight and 70 percent by weight; more preferred is between 40 percent by weight and 60 percent by weight; most preferred is between 45 percent by weight and 55 percent by weight.

Referring to FIG. 2, a multilayer construction 200 is provided according to the first aspect, including a barrier layer 20 having a major surface 21 and a sealing layer 22 comprising crosslinked silsesquioxane disposed on the major surface 21 of the barrier layer 20. The multilayer construction 200 further comprises a polymer layer 24 disposed adjacent to a major surface 23 of the barrier layer 20 opposite from the sealing layer 22. The polymer layer comprises a crosslinked polymer. In certain embodiments, the polymer layer is formed from one or more monomers selected from (meth)acrylates, vinyl ethers, vinyl naphthylene, thiols, acrylonitrile, multifunctional thiols, multifunctional allyl monomers, or multifunctional vinyl monomers.

In some embodiments, the composition of the polymer layer can further include one or more silicone (meth)acrylate additives in a range, for example, from about 0.01 wt % to about 10 wt %. In some embodiments, the content of silicone (meth)acrylate in a polymer layer may be no more than 15 wt %, no more than 10 wt %, or no more than 5 wt %. In some embodiments, the content may be no less than 0.005 wt %, no less than 0.01 wt %, no less than 0.02 wt %, or no less than 0.04 wt %. Silicone (meth)acrylate additives generally include a polydimethylsiloxane (PDMS) backbone and an alkoxy side chain with a terminal (meth)acrylate group. Such silicone (meth)acrylate additives are commercially available from various suppliers such as Tego Chemie under the trade designations “TEGO Rad 2100”, “TEGO Rad 2250”, “TEGO Rad 2300”, “TEGO Rad 2500”, and “TEGO Rad 2700”.

Based on NMR analysis “TEGO Rad 2100” and “TEGO Rad 2500” are believed to have the following chemical structure:

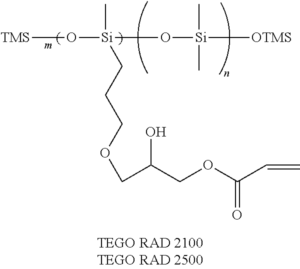

wherein n ranges from 10 to 20 and m ranges from 0.5 to 5. In some embodiments, n ranges from 14 to 16 and n ranges from 0.9 to 3. The molecular weight typically ranges from about 1000 g/mole to 2500 g/mole.

In some embodiments, a polymer layer can be formed from the same or different crosslinkable polymeric materials as polymeric matrix material. In some embodiments, the polymer layer can include a curable thiol-ene system which can be cured at air condition without nitrogen gas protection. In some embodiments, the thiol-ene material can include one or more cured thiol-ene resins from polythiol(s) and polyene(s) having a T_{g}>20° C. The thiol-ene system can include one or more of multifunctional thiol-ene monomers, multifunctional thiol-ene-acrylate monomer, and multifunctional thiol-acrylate monomers that are photo-polymerizable. The polymer layer of thiol-ene can include one or more polythiol monomers such as, for example, pentaerythritol tetra(3-mercaptopropionate), dipentaerythritol hexa(3-mercaptopropionate), di-pentaerythritolhexakis (3-mercaptopropionate), di-trimethylolpropanetetra (3-mercaptopropionate), tris[2-(3-mercaptopropionyloxy)ethyl]isocyanurate, ethoxylated trimethylpropantri(3-mercapto-propionate), ethoxylated trimethylpropantri(3-mercapto-propionate), polycaprolactone tetra(3-mercaptopropionate), 2,3-di((2-mercaptoethyl)thio)-1-propanethiol, dimercaptodiethylsulfide, trimethylolpropanetri(3-mercapto, glykoldi(3-mercaptopropionate), pentaerythritoltetramercaptoacetate, trimethylolpropanetrimercaptoacetate, glykoldimercaptoacetate, etc. The thiol-ene material of the polymer layer can further include one or more polyene monomers selected from polyacrylates, polymethacrylate, polyalkene, polyvinyl ether, polyallyl ether and their combinations. Examples of polyene are triallyl isocyanurate, tri(ethylene glycol) divinyl ether (TEGDVE), pentaerythritol allyl ether (TAE), and 2,4,6-triallyloxy-1,3,5-triazine (TOT), triallyl-1,3,5-triazine-2,4,6(1H,3H,5H)-trione (TTT). Other useful polyene monomers may be derived from the reaction of mono- or polyisocyanate with HX—R(CH═CH₂)ₙ, wherein HX is an isocyanate reactive group selected from —OH, —SH and —NH₂; R is a multivalent (hetero)hydrocarbyl group; and n is at least 1.

The polyalkene compounds may be prepared as the reaction product of a polythiol compound and an epoxy-alkene compound. Similarly, the polyalkene compound may be prepared by reaction of a polythiol with a di- or higher epoxy compound, followed by reaction with an epoxy-alkene compound. Alternatively, a polyamino compound may be reacted with an epoxy-alkene compound, or a polyamino compound may be reacted a di- or higher epoxy compound, followed by reaction with an epoxy-alkene compound.

The polyalkene may be prepared by reaction of a bis-alkenyl amine, such a HN(CH₂CH═CH₂), with either a di- or higher epoxy compound, or with a bis- or high (meth)acrylate, or a polyisocyanate.

The polyalkene may be prepared by reaction of a hydroxy-functional polyalkenyl compound, such as (CH₂═CH—CH₂—O)ₙ—R—OH with a polyepoxy compound or a polyisocyanate.

An oligomeric polyalkene may be prepared by reaction between a hydroxyalkyl (meth)acrylate and an allyl glycidyl ether.

In some preferred embodiments, the polyalkene and/or the polythiol compounds are oligomeric and prepared by reaction of the two with one in excess. For example, polythiols may be reacted with an excess of polyalkenes (e.g. in mole ratio of 1 to 5) initiated by thermal radical initiator or under photo irradiation such that an oligomeric polyalkene results having a functionality of at least two, as demonstrated below.

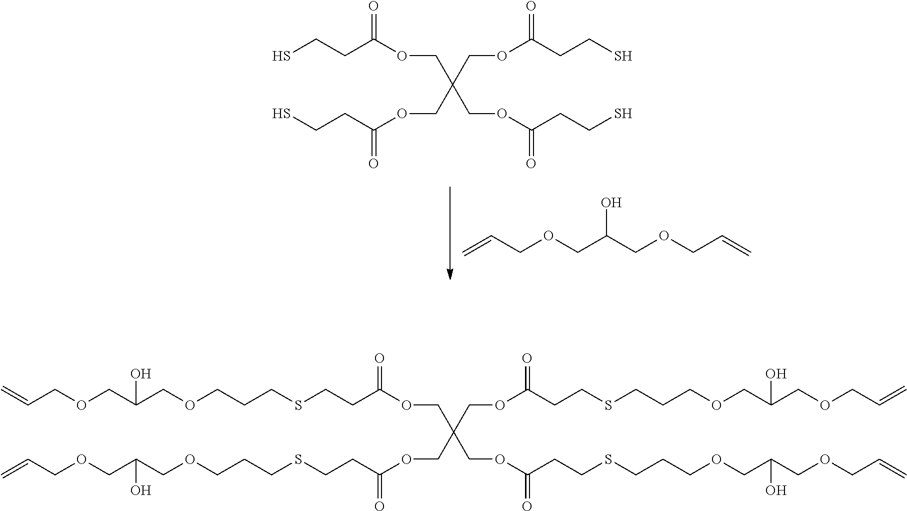 [SMILES: O=C(CCS)OCC(COC(=O)CCS)(COC(=O)CCS)COC(=O)CCS ; C=CCOCC(O)COCC=C ; C=CCOCC(O)COCCCSCCC(=O)OCC(COC(=O)CCSCCCOCC(O)COCC=C)(COC(=O)CCSCCCOCC(O)COCC=C)COC(=O)CCSCCCOCC(O)COCC=C]

Conversely an excess of polythiols may be reacted with the polyalkenes to form oligomeric polythiol results having a functionality of at least two.

In the following formulas, a linear thiol-alkene polymer is shown for simplicity. It will be understood that the pendent ene group of the first polymer will have reacted with the excess thiol, and the pendent thiol groups of the second polymer will have reacted with the excess alkene.

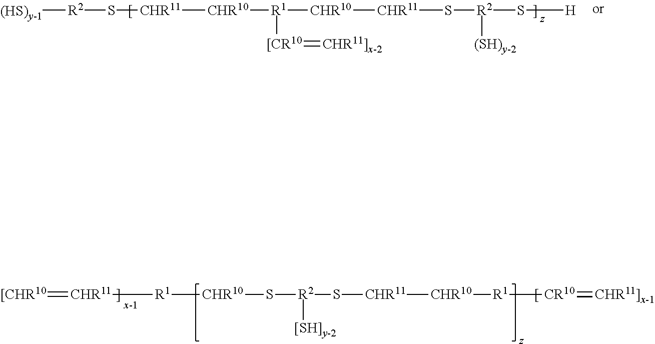

In some embodiments (meth)acrylates are used in the polymer layer composition. In some embodiments, a radiation curable methacrylate compound can increase the viscosity of the polymer layer composition and can reduce defects that could otherwise be created during the thermal acceleration of the thiol-alkene resin. Useful radiation curable methacrylate compounds have barrier properties to minimize the ingress of water and/or oxygen. In some embodiments, methacrylate compounds with a glass transition temperature (T_{g}) of greater than about 100° C. and substituents capable of forming high crosslink densities can provide a matrix with improved gas and water vapor barrier properties. In some embodiments, the radiation curable methacrylate compound is multifunctional, and suitable examples include, but are not limited to, those available under the trade designations SR 348 (ethoxylated (2) bisphenol A di(meth)acrylate), SR540 (ethoxylated (4) bisphenol A di(meth)acrylate), and SR239 (1,6-hexane diol di(meth)acrylate) from Sartomer USA, LLC, Exton, Pa.

The (meth)acrylate compound forms about 0 wt % to about 25 wt %, or about 5 wt % to about 25 wt % or about 10 wt % to about 20 wt %, of the polymer layer composition. In some embodiments, if the methacrylate polymer forms less than 5 wt % of the polymer layer composition, the (meth)acrylate compound does not adequately increase the viscosity of the composition to provide the thiol-alkene composition with a sufficient working time.

The content of the thiol-ene material by weight in a polymer layer can be, for example, in the range from about 10% to about 100%. In some embodiments, the polymer layer can include, for example, about 90 wt % or less, about 80 wt % or less, about 70 wt % or less, about 60 wt % or less, about 50 wt % or less, or about 40 wt % or less of the thiol-ene material. The polymer layer can include, for example, about 10 wt % or more, about 30 wt % or more, or about 50 wt % or more of the thiol-ene material.

In some embodiments, a polymer layer described herein can further include one or more crosslinkable acrylate materials such as, for example, pentaerythritol triacrylate, tris(hydroxy ethyl) isocyanurate triacrylate, etc. Especially preferred monomers that can be used to form the smooth layer include urethane acrylates (e.g., CN-968, T_{g}=about 84° C. and CN-983, T_{g}=about 90° C., both commercially available from Sartomer Co.), isobornyl acrylate (e.g., SR-506, commercially available from Sartomer Co., T_{g}=about 88° C.), dipentaerythritol pentaacrylates (e.g., SR-399, commercially available from Sartomer Co., T_{g}=about 90° C.), epoxy acrylates blended with styrene (e.g., CN-120580, commercially available from Sartomer Co., T_{g}=about 95° C.), di-trimethylolpropane tetraacrylates (e.g., SR-355, commercially available from Sartomer Co., T_{g}=about 98° C.), diethylene glycol diacrylates (e.g., SR-230, commercially available from Sartomer Co., T_{g}=about 100° C.), 1,3-butylene glycol diacrylate (e.g., SR-212, commercially available from Sartomer Co., T_{g}=about 101° C.), pentaacrylate esters (e.g., SR-9041, commercially available from Sartomer Co., T_{g}=about 102° C.), pentaerythritol tetraacrylates (e.g., SR-295, commercially available from Sartomer Co., T_{g}=about 103° C.), pentaerythritol triacrylates (e.g., SR-444, commercially available from Sartomer Co., T_{g}=about 103° C.), ethoxylated (3) trimethylolpropane triacrylates (e.g., SR-454, commercially available from Sartomer Co., T_{g}=about 103° C.), ethoxylated (3) trimethylolpropane triacrylates (e.g., SR-454HP, commercially available from Sartomer Co., T_{g}=about 103° C.), alkoxylated trifunctional acrylate esters (e.g., SR-9008, commercially available from Sartomer Co., T_{g}=about 103° C.), dipropylene glycol diacrylates (e.g., SR-508, commercially available from Sartomer Co., T_{g}=about 104° C.), neopentyl glycol diacrylates (e.g., SR-247, commercially available from Sartomer Co., T_{g}=about 107° C.), ethoxylated (4) bisphenol a dimethacrylates (e.g., CD-450, commercially available from Sartomer Co., T_{g}=about 108° C.), cyclohexane dimethanol diacrylate esters (e.g., CD-406, commercially available from Sartomer Co., T_{g}=about 110° C.), isobornyl methacrylate (e.g., SR-423, commercially available from Sartomer Co., T_{g}=about 110° C.), cyclic diacrylates (e.g., IRR-214, commercially available from UCB Chemicals, T_{g}=about 208° C.) and tris (2-hydroxy ethyl) isocyanurate triacrylate (e.g., SR-368, commercially available from Sartomer Co., T_{g}=about 272° C.), acrylates of the foregoing methacrylates and methacrylates of the foregoing acrylates.

In some embodiments, a polymer layer described herein can further include nanoparticles to improve barrier performance. The nanoparticles can be hosted by a matrix polymeric material or a binder of the polymer layer, e.g., being embedded within the crosslinkable polymeric material thereof. In some embodiments, the nanoparticles may be a mixture of nanoparticles including, for example, from about 10 wt % to 50 wt % of a first group of nanoparticles having an average particle diameter in a range from 2 nm to 200 nm, and from about 50 wt % to about 90 wt % of a second group of nanoparticles having an average particle diameter in a range from 60 nm to 400 nm. In some embodiments, the ratio of average particle diameters of the first group of nanoparticles and the second group of nanoparticles is in a range from 1:2 to 1:200.

In some embodiments, the nanoparticles can include inorganic nanoparticles. Examples of the inorganic nanoparticles include SiO₂, ZrO₂, or Sb doped SnO₂ nanoparticles, mixtures thereof, etc. Exemplary nanoparticles include SiO₂, ZrO₂, or Sb doped SnO₂ nanoparticles, and SiO₂ nanoparticles are commercially available, for example, from Nissan Chemical Industries, Ltd., Tokyo, Japan; C. I. Kasei Company, Limited, Tokyo, Japan; and Nalco Company, Naperville, Ill. ZrO₂, nanoparticles are commercially available, for example, from Nissan Chemical Industries. Sb doped SnO nanoparticles are commercially available, for example, from Advanced Nanoproducts, Sejong-si, South Korea.

The nanoparticles can consist essentially of or consist of a single oxide such as silica, or can comprise a combination of oxides, or a core of an oxide of one type (or a core of a material other than a metal oxide) on which is deposited an oxide of another type. The nanoparticles are often provided in the form of a sol containing a colloidal dispersion of inorganic oxide particles in liquid media. The sol can be prepared using a variety of techniques and in a variety of forms including hydrosols (where water serves as the liquid medium), organosols (where organic liquids so serve), and mixed sols (where the liquid medium contains both water and an organic liquid). The particles can be single size particles (e.g., ave. particle size of 20 nm) or different sized nanoparticle blend (e.g., blend of ave. particle size of 20 nm and 75 nm).

In some embodiments, nanoparticles can be modified, for example, by a surface treatment agent. A surface treatment agent may have a first end that will attach to the particle surface (covalently, ionically, or through strong physisorption) and a second end that imparts compatibility of the particle with the resin and/or reacts with resin during curing. Examples of surface treatment agents include alcohols, amines, carboxylic acids, sulfonic acids, phosphonic acids, silanes and titanates. In some embodiments, the treatment agent may be determined, in part, by the chemical nature of the metal oxide surface. In some embodiments, silanes are preferred for silica and other for siliceous fillers. In some embodiments, silanes and carboxylic acids are preferred for metal oxides such as zirconia.

In some embodiments, the polymer layer can have a thickness, for example, no less than about 200 nm, no less than about 500 nm, no less than about one micron, no less than about 2 microns, or no less than about 3 microns. In some embodiments, the polymer layer may have a thickness, for example, no more than about 30 microns, no more than about 20 microns, no more than about 10 microns, no more than about 5 microns, or no more than about 3 microns.

In some embodiments, the polymer layer can be formed by providing a coating composition on a major surface of a liner or a substrate. The coating composition can be applied using conventional coating methods such as roll coating (e.g., gravure roll coating, or die coating), spray coating (e.g., electrostatic spray coating) or die coating, then crosslinked using, for example, ultraviolet (UV) radiation or thermal curing. A polymer layer coating solution can be formed, for example, by mixing crosslinkable polymeric materials and nanoparticles dissolved in solvents with additives such as, for example, photoinitiator or catalysts. In some embodiments, the polymer layer can be formed by applying a layer of one or more monomers or oligomers and crosslinking the layer to form the polymer in situ, for example, by evaporation and vapor deposition of one or more crosslinkable monomers cured by heat or radiation, for example, using an electron beam apparatus, UV light source, electrical discharge apparatus or other suitable device. It is to be understood that in some embodiments, the polymer layer may be formed by any suitable processes other than a liquid coating process such as, for example, organic vapor deposition processes.

When the polymer layer is formed on a liner, the liner is preferably a release liner. Using a release liner allows formation of the multilayer construction on a substrate that is removable to result in a multilayer construction including the barrier layer, sealing layer, and polymer layer. Moreover, using a release liner provides the option of transferring the multilayer construction to another construction, a device, etc. The ability to transfer a multilayer barrier construction from a secondary, sacrificial and releasable substrate (e.g., liner) provides a number of benefits, including allowing for thinner total constructions and eliminating the difficulties of employing substrates (such as cyclic olefin polymer) in operations, such as sputter coating, in which the substrate is a fundamental limitation of process flexibility and yield.

In some embodiments, the composition of a polymer layer can include (a) (meth)acrylic oligomer and/or monomer binder in a range from 5 wt % to 60 wt %, (b) a mixture of nanoparticles in a range from 40 wt % to 95 wt % where 10 wt % to 50 wt % of the nanoparticles (NP-1) having 2 nm to 200 nm of particle size, and 50 to 90 wt % of the nanoparticles (NP-2) having 60 nm to 400 nm of particle size, and the ratio of the particle size of NP-1 and the one of NP-2 is in a range from 1:2 to 1:200; and (c) one or more silicone (meth)acrylate (e.g., PDMS acrylate) additives in a range from 0.01 to 15 wt %.

In some embodiments, a polymer layer can be made by a method including coating a mixture onto a first major surface of a substrate. The mixture can include at least one of acrylic, (meth)acrylic oligomer, or monomer binder in a range from 5 weight % to 60 weight %. The binder may further include one or more silicone (meth)acrylate (e.g., PDMS acrylate) additives. The mixture further include nanoparticles in a range from 40 to 95 weight %, based on the total weight of the mixture. The nanoparticles may have an average particle diameter in a range from 2 nm to 100 nm. The at least one of acrylic, (meth)acrylic oligomer, or monomer binder can be cured by heat or radiation to form the polymer layer.

In some embodiments, the polymer layer can have a thickness, for example, no less than about 50 nm, no less than about 100 nm, no less than about 200 nm, no less than about 500 nm, no less than about one micron, no less than about 2 microns, no less than about 3 microns, no less than about 4 microns, or no less than about 5 microns. Typical thicknesses of the polymer layer are between about 50 nm and about 5 microns, inclusive, such as between about 65 nm and about 2 microns, inclusive.

If desired, the polymer layer can be applied using conventional coating methods such as roll coating (e.g., gravure roll coating), die coating (e.g., slot die coating), or spray coating (e.g., electrostatic spray coating), then crosslinked using, for example, UV radiation. Some examples of suitable polymer layer materials and methods are disclosed in U.S. Pat. No. 8,034,452 (Padiyath et al.).

A polymer layer coating solution can be formed, for example, by mixing part A (e.g., thiol monomers) and part B (e.g., ene monomers) dissolved in solvents with additives such as, for example, photoinitiator or catalysts. In some embodiments, the polymer layer can be formed by applying a layer of one or more monomers or oligomers and crosslinking the layer to form the polymer in situ, for example, by evaporation and vapor deposition of one or more radiation-crosslinkable monomers cured by, for example, using an electron beam apparatus, UV light source, electrical discharge apparatus or other suitable device. It is to be understood that in some embodiments, the polymer layer may be formed by any suitable processes other than a liquid coating process such as, for example, organic vapor deposition processes.

Referring now to FIG. 3, a multilayer construction 300 is provided including a barrier layer 30 having a major surface 31 and a sealing layer 32 comprising crosslinked silsesquioxane disposed on the major surface 31 of the barrier layer 30. The multilayer construction 300 further comprises a polymer layer 36 disposed adjacent to a major surface 33 of the barrier layer 30 opposite from the sealing layer 32. Optionally, when a polymer layer is included, the multilayer construction further includes a substrate 34, wherein the polymer layer 36 is disposed between the substrate 34 and the barrier layer 30. Optionally, there is a primer coating layer (or called anchor coating layer, or called adhesion promoting layer) on the substrate to improve the adhesion between the substrate and the polymer layer. The substrate generally comprises glass, a flexible polymeric material, or a flexible metal foil. When the substrate is glass or metal foil, the barrier layer is typically employed to protect a device disposed on the glass or metal foil substrate, as the glass or metal foil acts as a barrier to one side of the device. Suitable polymeric materials include for instance and without limitation, a polyester, a polyacrylate, a polycarbonate, a polypropylene, a high density polyethylene, a low density polyethylene, a cyclic polyolefin, a polyethylene naphthalate, a polysulfone, a polyether sulfone, a polyurethane, a polyamide, a polyvinyl butyral, a polyvinyl chloride, a fluoropolymer, a polyvinylidene difluoride, a polyethylene sulfide, a cellulose derivative, a polyimide, a polyimide benzoxazole, a poly benzoxazole, or a combination thereof. In many embodiments, the substrate comprises a visible light-transmissive support. This can be particularly advantageous when the multilayer construction is also visible light transparent. In certain embodiments, the substrate comprises a microstructured major surface, a quantum dot particle, or a film. In embodiments including a substrate, the barrier layer is optionally deposited onto the substrate via vapor coating methods including sputtering, evaporation, chemical vapor deposition, atomic layer deposition, or plasma deposition on the substrate.

In certain embodiments, the barrier layer is formed via vapor coating methods including sputtering, evaporation, chemical vapor deposition, atomic layer deposition, or plasma deposition on the polymer layer.

Referring again to FIG. 3, in certain embodiments, the polymer layer 36 further comprises a plurality of inorganic nanoparticles 35. Such inorganic nanoparticles may include, for example and without limitation, metal nanoparticles, metal oxide nanoparticles, mixed metal oxide nanoparticles, or a combination thereof, for example silica nanoparticles, zirconia nanoparticles, alumina nanoparticles, titania nanoparticles, Indium doped tin oxide (ITO) nanoparticles, antimony doped tin oxide (ATO) nanoparticles, or a combination thereof. Moreover, the plurality of inorganic nanoparticles are optionally functionalized with acrylate groups, vinyl groups, mercapto groups, epoxy groups, or a combination thereof.

Referring to FIG. 4, a multilayer construction 400 is provided including a barrier layer 40 having a major surface 41 and a sealing layer 42 comprising crosslinked silsesquioxane disposed on the major surface 41 of the barrier layer 40. The multilayer construction 400 further comprises a polymer layer 46 disposed adjacent to a major surface 43 of the barrier layer 40 opposite from the sealing layer 42. The multilayer construction further includes a substrate 44, wherein the polymer layer 46 is disposed between the substrate 44 and the barrier layer 40. In addition, in certain embodiments the multilayer construction 400 comprises another layer 48 disposed on the substrate. The layer 48 comprises an adhesive, a second barrier layer, or a functional layer. When the layer 48 comprises an adhesive (e.g., a pressure sensitive adhesive or a hot melt adhesive), the multilayer construction 400 may be readily adhered to another material, such as a portion of a device. When the layer 48 comprises a second barrier layer, the multilayer construction 400 may have enhanced protection from vapor or gas (e.g., moisture and/or oxygen) transport through the construction. When the layer 48 comprises a functional layer, the multilayer construction 400 may have additional functions such as antistatic, anti-reflection, anti-scratch, easy-cleaning, or any combination of these functions.

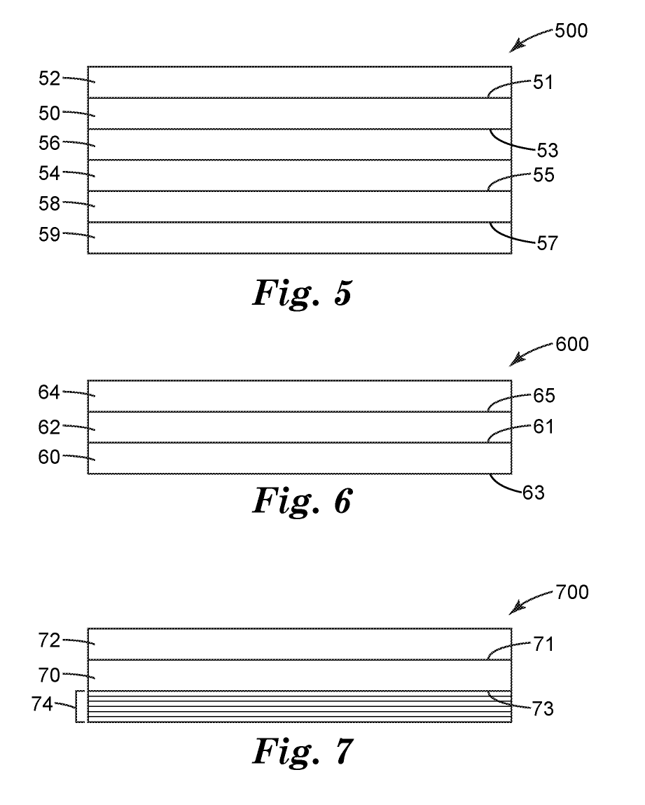

Referring FIG. 5, a multilayer construction 500 is provided including a (first) barrier layer 50 having a major surface 51 and a (first) sealing layer 52 comprising crosslinked silsesquioxane disposed on the major surface 51 of the barrier layer 50. The multilayer construction 500 further comprises a polymer layer 56 disposed adjacent to a major surface 53 of the barrier layer 50 opposite from the sealing layer 52. In addition, the multilayer construction 500 comprises a second barrier layer 58 disposed on a major surface 55 of the substrate 54 opposite of the first barrier layer 50, and a second sealing layer 59 disposed on the major surface 57 of the second barrier layer 58. In most embodiments, the second sealing layer comprises crosslinked silsesquioxane. Optionally, a second polymeric layer (not shown) is disposed between the substrate and the second barrier layer.

Referring to FIG. 6, a multilayer construction 600 is provided including a barrier layer 60 having a major surface 61 and a sealing layer 62 comprising crosslinked silsesquioxane disposed on the major surface 61 of the barrier layer 60. The multilayer construction 600 further comprises an additional layer 64 disposed on (or adjacent to) a major surface 65 of the sealing layer 62 opposite from the barrier layer 60. In some embodiments, the additional layer 64 comprises an adhesive, for instance a pressure sensitive adhesive or a hot melt adhesive. In certain embodiments, the additional layer 64 comprises a functional layer selected from an antistatic layer, an easy-clean layer, an anti-scratch layer, an anti-reflection layer, a hardcoat layer, or a combination thereof.

The present disclosure also provides a third aspect. The third aspect includes a device comprising the multilayer construction of any embodiment of the first aspect or the second aspect. The device is selected from a light generating device, a display, a solar cell, or a vacuum insulation panel. For instance, the device optionally comprises an organic light emitting diode (OLED), an inorganic light emitting device, or a quantum dot light emitting device.

Referring to FIG. 7, a device 700 is provided including a barrier layer 70 having a major surface 71 and a sealing layer 72 comprising crosslinked silsesquioxane disposed on the major surface 71 of the barrier layer 70. The multilayer construction 700 further comprises a portion of a device 74 disposed on a second major surface 73 of the barrier layer 70. The device is typically a light generating device (e.g., an organic light emitting device, an inorganic light emitting device, or a quantum dot light emitting device), a display, a solar cell, or a vacuum insulation panel. A suitable device is often visible light transmissive. Certain devices comprise multilayer constructions 74, as illustrated in FIG. 7.

### EXEMPLARY EMBODIMENTS

Embodiment 1 is a multilayer construction including a barrier layer having a major surface and a sealing layer comprising crosslinked silsesquioxane disposed on the major surface of the barrier layer. The multilayer construction further comprises a polymer layer disposed adjacent to a major surface of the barrier layer opposite from the sealing layer.

Embodiment 2 is the multilayer construction of embodiment 1, wherein the barrier layer is a film.

Embodiment 3 is the multilayer construction of embodiment 1 or embodiment 2, wherein the barrier layer is a film having a thickness of less than 1 micron.

Embodiment 4 is the multilayer construction of any of embodiments 1 to 3, wherein the barrier layer is selected from a layer of a metal, a metal oxide, a mixture of metals, a mixture of metal oxides, a metal nitride, a metal carbide, a metal oxynitride, a metal oxycarbide, a mixture of metal carbides, a mixture of metal nitrides, a mixture of metal oxycarbides, a mixture of metal oxynitrides, or a combination thereof.

Embodiment 5 is the multilayer construction of any of embodiments 1 to 4, wherein the barrier layer is selected from a layer of aluminum, indium, germanium, tin, antimony, bismuth, aluminosilicate, alumina, zirconia, titania, silica, SiₓO_{y}N_{z}, SiON, silicon nitride, SiₓAl_{y}O_{z}, diamond-like glass (DLG) or SiₓO_{y}C_{z}.

Embodiment 6 is the multilayer construction of any of embodiments 1 to 5, wherein the barrier layer is inorganic.

Embodiment 7 is the multilayer construction of any of embodiments 1 to 5, wherein the barrier layer is a layer of diamond-like glass (DLG).

Embodiment 8 is the multilayer construction of any of embodiments 1 to 7, wherein the multilayer construction further comprises a substrate disposed adjacent to a major surface of the barrier layer opposite from the sealing layer, wherein the polymer layer is disposed between the barrier layer and the substrate.

Embodiment 9 is the multilayer construction of any of embodiments 1 to 8, wherein the polymer layer is formed from one or more monomers selected from (meth)acrylates, vinyl ethers, vinyl naphthylene, thiols, acrylonitrile, multifunctional thiols, multifunctional allyl monomers, or multifunctional vinyl monomers.

Embodiment 10 is the multilayer construction of any of embodiments 1 to 9, further comprising an adhesive layer disposed adjacent to the polymer layer.

Embodiment 11 is the multilayer construction of embodiment 9, wherein the polymer layer comprises one or more cured thiol-ene resins from polythiol(s) and polyene(s) having a T_{g}>20° C.

Embodiment 12 is the multilayer construction of any of embodiments 9 to 11, the polymer layer includes one or more silicone (meth)acrylate additives.

Embodiment 13 is the multilayer construction of any of embodiments 1 to 12, wherein the polymer layer further comprises a plurality of nanoparticles.

Embodiment 14 is the multilayer construction of embodiment 8, wherein the substrate comprises glass, a flexible polymeric material, or a flexible metal foil.

Embodiment 15 is the multilayer construction of embodiment 8 or embodiment 14, wherein the substrate comprises a polyester, a polyacrylate, a polycarbonate, a polypropylene, a high density polyethylene, a low density polyethylene, a cyclic polyolefin, a polyethylene naphthalate, a polysulfone, a polyether sulfone, a polyurethane, a polyamide, a polyvinyl butyral, a polyvinyl chloride, a fluoropolymer, a polyvinylidene difluoride, a polyethylene sulfide, a cellulose derivative, a polyimide, a polyimide benzoxazole, a poly benzoxazole, or a combination thereof.

Embodiment 16 is the multilayer construction of embodiment 8, embodiment 14, or embodiment 15, wherein the substrate comprises a visible light-transmissive support.

Embodiment 17 is the multilayer construction of any of embodiments 8 or 14 to 16, wherein the substrate comprises a microstructured major surface.

Embodiment 18 is the multilayer construction of any of embodiments 8 or 14 to 16, wherein the substrate comprises a quantum dot particle or a film.

Embodiment 19 is the multilayer construction of any of embodiments 1 to 18, wherein the barrier layer is deposited by sputtering, evaporation, chemical vapor deposition, atomic layer deposition, or plasma deposition on a substrate or on a polymer layer.

Embodiment 20 is the multilayer construction of any of embodiments 1 to 19, wherein the sealing layer further comprises a plurality of inorganic nanoparticles.

Embodiment 21 is the multilayer construction of embodiment 20, wherein the plurality of inorganic nanoparticles comprise metal nanoparticles, metal oxide nanoparticles, mixed metal oxide nanoparticles, or a combination thereof.

Embodiment 22 is the multilayer construction of embodiment 21, wherein the plurality of inorganic nanoparticles comprise silica nanoparticles.

Embodiment 23 is the multilayer construction of embodiment 21, wherein the plurality of inorganic nanoparticles comprise zirconia nanoparticles, alumina nanoparticles, titania nanoparticles, indium doped tin oxide (ITO), antimony doped tin oxide (ATO), or a combination thereof.

Embodiment 24 is the multilayer construction of any of embodiments 20 to 23, wherein the plurality of inorganic nanoparticles are functionalized with acrylate groups, vinyl groups, mercapto groups, epoxy groups, or a combination thereof.

Embodiment 25 is the multilayer construction of any of embodiments 1 to 24, wherein the crosslinked silsesquioxane is formed from functionalized silsesquioxanes comprising acrylate groups, vinyl groups, mercapto groups, epoxy groups, or a combination thereof.

Embodiment 26 is the multilayer construction of any of embodiments 1 to 25, further comprising an adhesive disposed on the sealing layer.

Embodiment 27 is the multilayer construction of any of embodiments 14 to 18, further comprising an adhesive disposed on the substrate.

Embodiment 28 is the multilayer construction of any of embodiments 8 or 14 to 18, further comprising a second barrier layer having a major surface, the second barrier layer disposed on a major surface of the substrate opposite of the barrier layer and sealing layer.

Embodiment 29 is the multilayer construction of embodiment 28, further comprising a second sealing layer comprising crosslinked silsesquioxane disposed on the major surface of the second barrier layer.

Embodiment 30 is the multilayer construction of embodiment 29, further comprising a second polymeric layer disposed between the substrate and the second barrier layer.

Embodiment 31 is the multilayer construction of any of embodiments 1 to 30, further comprising a functional layer disposed on a major surface of the sealing layer, the functional layer selected from an antistatic layer, an easy-clean layer, an anti-scratch layer, an anti-reflection layer, a hardcoat layer, or a combination thereof.

Embodiment 32 is a multilayer construction. The multilayer construction includes a barrier layer having a major surface and a sealing layer comprising crosslinked silsesquioxane disposed on the major surface of the barrier layer. The multilayer construction further includes a substrate disposed adjacent to a major surface of the barrier layer opposite from the sealing layer and a polymer layer comprising a crosslinked polymer disposed between the barrier layer and the substrate.

Embodiment 33 is the multilayer construction of embodiment 32, wherein the barrier layer is a film.

Embodiment 34 is the multilayer construction of embodiment 32 or embodiment 33, wherein the barrier layer is a film having a thickness of less than 1 micron.

Embodiment 35 is the multilayer construction of any of embodiments 32 to 34, wherein the barrier layer is selected from a layer of a metal, a metal oxide, a mixture of metals, a mixture of metal oxides, a metal nitride, a metal carbide, a metal oxynitride, a metal oxycarbide, a mixture of metal carbides, a mixture of metal nitrides, a mixture of metal oxycarbides, a mixture of metal oxynitrides, or a combination thereof.

Embodiment 36 is the multilayer construction of any of embodiments 32 to 35, wherein the barrier layer is selected from a layer of aluminum, indium, germanium, tin, antimony, bismuth, aluminosilicate, alumina, zirconia, titania, silica, SiₓO_{y}N_{z}, SiON, silicon nitride, SiₓAl_{y}O_{z}, diamond-like glass (DLG) or SiₓO_{y}C_{z}.

Embodiment 37 is the multilayer construction of any of embodiments 32 to 36, wherein the barrier layer is inorganic.

Embodiment 38 is the multilayer construction of any of embodiments 32 to 36, wherein the barrier layer is a layer of diamond-like glass (DLG).

Embodiment 39 is the multilayer construction of any of embodiments 32 to 38, the polymer layer is formed from one or more monomers selected from (meth)acrylates, vinyl ethers, vinyl naphthylene, thiols, acrylonitrile, multifunctional thiols, multifunctional allyl monomers, or multifunctional vinyl monomers.

Embodiment 40 is the multilayer construction of any of embodiments 32 to 39, wherein the polymer layer further comprises a plurality of nanoparticles.

Embodiment 41 is the multilayer construction of any of embodiments 32 to 40, wherein the substrate comprises glass, a flexible polymeric material, or a flexible metal foil.

Embodiment 42 is the multilayer construction of any of embodiments 32 to 41, wherein the substrate comprises a polyester, a polyacrylate, a polycarbonate, a polypropylene, a high density polyethylene, a low density polyethylene, a cyclic polyolefin, a polyethylene naphthalate, a polysulfone, a polyether sulfone, a polyurethane, a polyamide, a polyvinyl butyral, a polyvinyl chloride, a fluoropolymer, a polyvinylidene difluoride, a polyethylene sulfide, a cellulose derivative, a polyimide, a polyimide benzoxazole, a poly benzoxazole, or a combination thereof.

Embodiment 43 is the multilayer construction of any of embodiments 32 to 42, wherein the substrate comprises a visible light-transmissive support.

Embodiment 44 is the multilayer construction of any of embodiments 32 to 43, wherein the substrate comprises a microstructured major surface.

Embodiment 45 is the multilayer construction of any of embodiments 32 to 43, wherein the substrate comprises a quantum dot particle or a film.

Embodiment 46 is the multilayer construction of any of embodiments 32 to 45, wherein the barrier layer is deposited by sputtering, evaporation, chemical vapor deposition, atomic layer deposition, or plasma deposition on the substrate or on the polymer layer.

Embodiment 47 is the multilayer construction of any of embodiments 32 to 46, wherein the sealing layer further comprises a plurality of inorganic nanoparticles.

Embodiment 48 is the multilayer construction of embodiment 47, wherein the plurality of inorganic nanoparticles comprise metal nanoparticles, metal oxide nanoparticles, mixed metal oxide nanoparticles, or a combination thereof.

Embodiment 49 is the multilayer construction of embodiment 48, wherein the plurality of inorganic nanoparticles comprise silica nanoparticles.

Embodiment 50 is the multilayer construction of embodiment 48, wherein the plurality of inorganic nanoparticles comprise zirconia nanoparticles, alumina nanoparticles, titania nanoparticles, indium doped tin oxide (ITO), antimony doped tin oxide (ATO), or a combination thereof.

Embodiment 51 is the multilayer construction of any of embodiments 47 to 50, wherein the plurality of inorganic nanoparticles are functionalized with acrylate groups, vinyl groups, mercapto groups, epoxy groups, or a combination thereof.

Embodiment 52 is the multilayer construction of any of embodiments 32 to 51, wherein the crosslinked silsesquioxane is formed from functionalized silsesquioxanes comprising acrylate groups, vinyl groups, mercapto groups, epoxy groups, or a combination thereof.

Embodiment 53 is the multilayer construction of any of embodiments 32 to 52, further comprising an adhesive disposed on the sealing layer.

Embodiment 54 is the multilayer construction of any of embodiments 32 to 53, further comprising an adhesive disposed on the substrate.

Embodiment 55 is the multilayer construction of any of embodiments 32 to 54, further comprising a second barrier layer having a major surface, the second barrier layer disposed on a major surface of the substrate opposite of the barrier layer and sealing layer.

Embodiment 56 is the multilayer construction of embodiment 55, further comprising a second sealing layer comprising crosslinked silsesquioxane disposed on the major surface of the second barrier layer.

Embodiment 57 is the multilayer construction of embodiment 56, further comprising a second polymeric layer disposed between the substrate and the second barrier layer.

Embodiment 58 is the multilayer construction of any of embodiments 32 to 57, further comprising a functional layer disposed on a major surface of the sealing layer, the functional layer selected from an antistatic layer, an easy-clean layer, an anti-scratch layer, an anti-reflection layer, a hardcoat layer, or a combination thereof.

Embodiment 59 is a device comprising the multilayer construction of any of embodiments 1 to 58, the device selected from a light generating device, a display, a solar cell, or a vacuum insulation panel.

Embodiment 60 is the device of embodiment 59, wherein the device comprises an organic light emitting diode (OLED).

Embodiment 61 is the device of embodiment 59, wherein the device comprises an inorganic light emitting device.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Summary of Materials

Unless otherwise noted, all parts, percentages, ratios, etc. in the Examples and the rest of the specification are by weight. Table 1 provides a role and a source for materials used in the Examples below:

TABLE 1

| Product name | Material | Source |
|---|---|---|
| Acrylate-SSQ | Silsesquioxane with acrylate-group | Preparatory Example 2 |
| VSSQ | Silsesquioxane with vinyl-group | Preparatory Example 1 |
| | (LTC10016040) | |
| SH-20 nm SiO₂ | 3-mercaptopropyltrimethoxysilane | Preparatory Example 3 |
| | surface modified 20 nm silica, 49.04 | |
| | wt % solid | |
| MVBF-1000 film | 1 mil barrier film with multilayer | Preparatory Example 4 |
| | structure of PET/hard coat/DLG | |
| Vinyltriethoxysilane | Monomer | Gelest, Inc. (Morrisville, PA) |
| Hexamethyldisiloxane | Encapsulating agent | Gelest, Inc. (Morrisville, PA) |
| Ethoxytrimethylsilane | Encapsulating agent | Gelest, Inc. (Morrisville, PA) |
| MA-SSQ | 3- | Nanjing Shuguang |
| | methacryloxypropyltrimethoxysilane | Organosilicone Co. (Nanjing, |
| | (KH570) | Jiangsu Province, China) |
| A174-20 nm SiO₂ | A174 surface modified 20 nm silica | Preparatory Example 5 |
| | nanoparticle, 46.7 wt % solid | |
| A174-5 nm SiO₂ | A174 surface modified 5 nm silica | Preparatory Example 6 |
| | nanoparticle, 46.4 wt % solid | |
| Nalco 2327 | 20 nm silica nanoparticle in water, | Ecolab Company (St. Paul, |
| | 40 wt % solid | MN) |
| Nalco 2326 | 5 nm silica nanoparticle in water, 15 | Ecolab Company (St. Paul, |
| | wt % solid | MN) |
| SH-silane | 3-mercaptopropyltrimethoxysilane | Chemical Agent Co., Ltd., |
| | | Guoyao Group (Shanghai, |
| | | China) |
| IRGACURE 184 | Photo-initiator | BASF SE (Ludwigshafen, |
| | | Germany) |
| LUCIRIN TPO | 2,4,6-trimethylbenzoyldiphenyl | BASF Corp. (Florham Park, |
| | phosphine oxide | NJ) |
| PROSTAB 5198 | 4-hydroxy-2,2,6,6- | BASF Corp. (Florham Park, |
| | tetramethylpiperidinyloxy | NJ) |
| Propylene glycol | 1-methoxy-2-propanol | Sigma-Aldrich Chemical |
| methyl ether | | Company (St. Louis, MO) |
| Heptanes | Mixture of linear and branched | Sigma-Aldrich Chemical |
| | heptanes | Company (St. Louis, MO) |
| Tartaric Acid | 2,3-dihydroxybutanedioic acid | Sigma-Aldrich Chemical |
| | | Company (St. Louis, MO) |
| MEK | Methyl ethyl ketone | Sigma-Aldrich Chemical |
| | | Company (St. Louis, MO) |
| IPA | Iso-propanol | Sigma-Aldrich Chemical |
| | | Company (St. Louis, MO) |

Water Vapor Transmission Rate (WVTR) Test:

The WVTR test was performed on a Mocon AQUATRAN 2MW (Mocon Inc., Minneapolis, Minn.), at 50° C. and 100% relative humidity (RH), with results provided in the units of grams per square meter-day. The WVTR test method using the Mocon AQUATRAN 2MW is a modified ASTM F1249 using a coulometric sensor for increased sensitivity.

### Preparatory Example 1—Vinyl-SSQ Synthesis

Vinyl-SSQ was synthesized as follows: 100 g (0.52 moles) of vinyltriethoxysilane, 50 g of distilled water, and 1.0 g of tartaric acid were mixed together at room temperature in a 500 mL round bottom flask equipped with a condenser. The mixture was stirred at room temperature, and after 20 minutes of stirring an exotherm was observed; thereafter the temperature was maintained at 70° C. for 3-4 hours. To encapsulate the silanol groups, 80 g of ethoxytrimethylsilane was added to the reaction mixture, followed by stirring at 70° C. for 3 hours. Evaporation of the solvents yielded vinylsilsesquioxane as a viscous liquid, which was dissolved in 200 mL of heptanes. The heptanes solution was passed through 1-micron filter paper leading to the separation of insoluble tartaric acid. The evaporation of heptanes at 100° C. and under reduced pressure yielded vinylsilsesquioxane with reduced silanol end groups as a gummy liquid.

### Preparatory Example 2—Acrylate-SSQ Synthesis

Acrylate-SSQ was synthesized as follows: 2643 g of methylacryloyl-silsesquioxane (MA-SSQ monomer) was added into 1000 g water and 5 g HCl (37%), and the mixture was stirred at room temperature until an exotherm was observed. After stirring for another 5 minutes, 289.5 g of hexamethyldisiloxane was added as an encapsulating agent to encapsulate the silanol groups. The mixture was stirred at 30° C. for 8 hours. Evaporation of the solvents by distillation under reduced pressure yielded a viscous MA-SSQ. Next, the viscous liquid was dissolved in 500 mL of MEK and washed with 800 mL of water for one time in a separatory funnel, then the water was separated from MEK solution and moved from the bottom of separatory funnel. The MEK of the organic phase was evaporated again by distillation under reduced pressure, resulting in final product of MA-SSQ as optically clear viscous liquid. The silanol group in the Acrylate-SSQ was capped with hexamethyldisiloxane, and the mole ratio for capped silanol was 11.1 mole %.

### Preparatory Example 3—SH-20 nm SiO₂ Preparation

100 grams of Nalco 2327 were charged into a 3-neck flask, and under stirring 100 grams of 1-methoxy-2-propanol and 4.8 grams of SH-silane (100% coverage) were added. The mixture was stirred under a nitrogen atmosphere and heat to 80° C. to react for 3 hours, obtaining a white solution. After the reaction, 88 g of 1-methoxy-2-propanol was added into the resultant solution.

The water was removed from the above solution with a rotary evaporator at 60° C. and −0.095 MPa for 20 minutes. 55 g of 1-methoxy-2-propanol was charged into the resultant solution and then the remaining water was removed by further distillation with the rotary evaporator at 60° C. and −0.095 MPa. The functionalized silica nanoparticles were 49.04 wt % of the final product.

### Preparatory Example 4—MVBF-1000 Film Preparation

MVBF-1000 Film was prepared by first applying a hardcoat according to the method described in WO2012/125324A1 to a coating thickness of 1 micron, with 10% by weight of silica nanoparticles on a dry basis, on 1.1 mil PET film. The hardcoated PET film was plasma treated in the same manner as described in WO2012/125324A1, except that hexamethyldisiloxane (HMDSO, available from Gelest Corporation) vapor and oxygen gas were used in the plasma. The conditions of plasma treatment are summarized below:

HMDSO Vapor Flow Rate: 155 standard cubic centimeters per minute (std.cm³/min)

Oxygen Flow Rate: 660 std.cm³/min

Rf Power: 8500 watts

Line Speed: 10 feet/minute

### Preparatory Example 5—A174-20 nm Silica

A 1000 mL 3-neck flask equipped with a stir bar, stir plate, condenser, heating mantle and thermocouple/temperature controller was charged with 300 grams of Nalco 2327 (a 40 wt. % solids dispersion of approximately 20 nm diameter colloidal silica in water available from Nalco Chemical Company, Naperville Ill.). To this dispersion, 350 grams of 1-methoxy-2-propanol was added with stirring. Next, 18.45 grams of 97% 3-(methacryloxypropyl)trimethoxysilane, 0.30 grams of a 5% aqueous solution of PROSTAB 5198 and 50 grams of 1-methoxy-2-propanol was added to a 100 ml poly beaker. The premix of 3-(methacryloxypropyl)trimethoxysilane/PROSTAB 5198/1-methoxy-2-propanol premix was added to the batch with stirring. The beaker containing the premix was rinsed with aliquots of 1-methoxy-2-propanol totaling 50 grams. The rinses were added to the batch. At this point the batch was a translucent, low-viscosity dispersion. The batch was heated to 80° C. and held for approximately 16 hours. The batch was cooled to room temperature and transferred to a 2000 mL 1-neck flask. The reaction flask was rinsed with 100 grams of 1-methoxy-2-propanol and the rinse was added to the batch. An additional 250 grams of 1-methoxy-2-propanol was added to the flask to aid in the 1-methoxy-2-propanol/water azeotrope distillation. The batch was heated/distilled under vacuum on a Rotavapor to result in a translucent dispersion containing 42 wt. % solids of surface-modified silica particles in 1-methoxy-2-propanol.

### Preparatory Example 6—A174-5 nm Silica

A 2000 mL 3-neck flask equipped with a stir bar, stir plate, condenser, oil bath and thermocouple/temperature controller was charged with 1100 grams of Nalco 2326. To this dispersion, 1140 grams of 1-methoxy-2-propanol was added with stirring. Next, a premix of 98.81 grams of 97% 3-(methacryloxypropyl)trimethoxysilane, 100 grams of 1-methoxy-2-propanol and 0.005 grams of PROSTAB 5198 were added to the batch with stirring. At this point the batch was a translucent, low-viscosity dispersion. The batch was heated to 80° C. and held for approximately 16 hours. The batch was cooled to room temperature and part of the batch was transferred to a 2000 mL 1-neck flask. The reaction flask was rinsed with 100 grams of 1-methoxy-2-propanol and the rinse was added to the batch. The batch was heated/distilled under vacuum on a Rotavapor. Additional 1-methoxy-2-propanol was added to the flask in portions to aid in the 1-methoxy-2-propanol/water azeotrope distillation. The remainder of the batch was also added as volume allowed. The final result was a clear, colorless dispersion containing 46.4 wt % solids of surface-modified silica particles in 1-methoxy-2-propanol.

### Example Sealing Layer Solutions Preparation

CS-1:

2.28 g of vinyl-SSQ was added into a mixture of 8.63 g of IPA and 2.09 g of 46.7 wt. % A174-20 nm silica solution, then stirred to obtain a clear solution. Next, 0.16 g of photoinitiator IRGACURE 184 was added to get a 25 wt. % solid solution, with a photoinitiator content of 5 wt. % of the total solids.

CS-2 through CS-6:

The same procedure was followed as that for the CS-1 preparation, except with the different functionalized silica nanoparticle loading, different silsesquioxane chemistry, or different functionalized silica nanoparticle, as provided below in Table 2.

CS-7:

The same procedure was followed as that for the CS-1 preparation, except that the functionalized silica nanoparticles were replaced with Acrylate-SSQ. The weight ratio of vinyl-SSQ to acrylate-SSQ was 50:50 and the total solids content was 25 wt. % of the solution.

CS-8:

3.25 g of vinyl-SSQ was added into 9.75 g of 50:50 IPA/MEK, and stirred to let it dissolve. Next, 0.16 g of the photoinitiator IRGACURE 184 was added to obtain a 25 wt. % solids solution with a photoinitiator content of 5 wt. % of the total solids.

CS-9:

3.25 g of acrylate-SSQ was added into 9.75 g of 50:50 IPA/MEK, and stirred to let it dissolve. Next, 0.16 g of the photoinitiator Irgacure 184 was added to get a 25 wt. % solids solution with a photoinitiator content of 5 wt. % of the total solids.

CS-10:

Into a 20 ml jar, 3.379 g A174-5 nm silica solution (46.4 wt. %) and 6.196 g A174-20 nm silica solution were placed, and the jar was shaken to get a uniform solution. Next, 4.425 g of IPA was added and the jar was shaken to get uniform solution, followed by 3.379 g of ASSQ added, and the jar was shaken to get uniform solution. Finally, 0.32 g of LUCIRIN TPO was added and the jar was shaken to dissolve the LUCIRIN TPO to get a 40.2 wt. % solids solution with a photoinitiator content of 5 wt. % of the total solids.

TABLE 2
Sealing layer solutions

| | | Functionalized | SSQ:Function- | Total |
|---|---|---|---|---|
| Example | SSQ | silica | alized | solid |
| no. | chemistry | nanoparticle | silica (w:w) | (wt %) |
| CS-1 | Vinyl-SSQ | A174-20 nm silica | 70:30 | 25% |
| CS-2 | Vinyl-SSQ | A174-20 nm silica | 50:50 | 25% |
| CS-3 | Acrylate- | A174-20 nm silica | 70:30 | 25% |
| | SSQ | | | |
| CS-4 | Vinyl-SSQ | SH silane-20 nm | 50:50 | 25% |
| | | silica | | |
| CS-5 | Vinyl-SSQ | A174-20 nm silica | 50:50 | 8% |
| CS-6 | Acrylate- | A174-20 nm silica | 70:30 | 8% |
| | SSQ | | | |
| CS-7 | Acrylate- | — | — | 25% |
| | SSQ and | | | |
| | Vinyl-SSQ | | | |
| | (50:50) | | | |
| CS-8 | Vinyl-SSQ | — | — | 25% |
| CS-9 | Acryalte- | — | — | 25% |
| | SSQ | | | |
| CS-10 | Acrylate- | A174-5 nm silica | 30:70 | 40.2% |
| | SSQ | A174-20 nm silica = | | |
| | | 35:65 | | |

Sealing Layer Coated Sample Preparation:

EX-SCS-1:

An A4 size (20 cm×30 cm) multilayer construction MVBF-1000 was cut, and the coating solution prepared as CS-1 was coated onto the DLG side, with a 25# bar (at a wet thickness of 25 micrometers). Next, the coated construction was put into an 80° C. oven for 5 minutes, followed by curing under UV radiation using a HOK 35/120 arc lamp at 100% intensity, 6 m/min speed, several passes. The UV machine was a PL-300UV made by Shanghai Yiying Printing Machine Co., Ltd., Shanghai, China, to obtain a cured multilayer construction.

EX-SCS-2 through EX-SCS-10:

The same procedure as EX-SCS-1 was followed with different coating solutions and different coating thicknesses, as shown below in Table 3.

EX-SCS-11 and EX-SCS-12:

Coating was done in a pilot clean coater. The coating conditions included pumping the sealing layer solutions through a slot die using a pump at a speed of 60 rpm. The oven was set to 85° C. and had a total length of 12 meters. The multilayer construction traveled through the clean coater at a web speed of 2.5 meters per minute. The sealing layer solutions were cured using an H bulb at 70% intensity, in a nitrogen atmosphere.

TABLE 3
WVTR performance results

| | | | | Dry | |
|---|---|---|---|---|---|
| | | | | Thick- | WVTR(g/ |
| Example | Film | Coating | | ness | m2-day@50 |
| no. | substrate | solution | Wetting | (μm) | C./100% RH) |
| EX-SCS-1 | DLG | CS-1 | good | 6.2 | 0.0050 |
| EX-SCS-2 | surface of | CS-2 | good | 6.2 | 0.0050 |
| EX-SCS-3 | MVBF-1000 | CS-3 | good | 6.2 | 0.0050 |
| EX-SCS-4 | | CS-4 | good | 6.2 | 0.0098 |
| EX-SCS-5 | | CS-7 | good | 6.2 | 0.0048 |
| EX-SCS-6 | | CS-8 | good | 6.2 | 0.0094 |
| EX-SCS-7 | | CS-9 | de- | 6.2 | / |
| | | | wetting | | |
| EX-SCS-8 | | CS-10 | good | 4.8 | 0.0091 |
| EX-SCS-9 | | CS-10 | good | 2.4 | 0.0082 |
| EX-SCS-10 | | CS-10 | good | 1.2 | 0.0049 |
| EX-SCS-11 | | CS-5 | good | — | 0.0062 |
| EX-SCS-12 | | CS-6 | good | — | 0.0030 |
| Control 1 | MVBF-1000 | — | — | — | 0.0120 |

While the specification has described in detail certain exemplary embodiments, it will be appreciated that those skilled in the art, upon attaining an understanding of the foregoing, may readily conceive of alterations to, variations of, and equivalents to these embodiments. Furthermore, all publications and patents referenced herein are incorporated by reference in their entirety to the same extent as if each individual publication or patent was specifically and individually indicated to be incorporated by reference. Various exemplary embodiments have been described. These and other embodiments are within the scope of the following claims.

1. A multilayer construction comprising:
a barrier layer having a major surface;
a sealing layer comprising crosslinked silsesquioxane disposed on the major surface of the barrier layer; and
a polymer layer comprising a crosslinked polymer disposed adjacent to a major surface of the barrier layer opposite from the sealing layer.

2. The multilayer construction of claim 1, wherein the barrier layer is a film having a thickness of less than 1 micron.

3. The multilayer construction of claim 1, wherein the barrier layer is selected from a layer of a metal, a metal oxide, a mixture of metals, a mixture of metal oxides, a metal nitride, a metal carbide, a metal oxynitride, a metal oxycarbide, a mixture of metal carbides, a mixture of metal nitrides, a mixture of metal oxycarbides, a mixture of metal oxynitrides, or a combination thereof.

4. The multilayer construction of claim 1, wherein the barrier layer is selected from a layer of aluminum, indium, germanium, tin, antimony, bismuth, aluminosilicate, alumina, zirconia, titania, silica, SiₓO_{y}N_{z}, SiON, silicon nitride, SiₓAl_{y}O_{z}, diamond-like glass (DLG) or SiₓO_{y}C_{z}.

5. The multilayer construction of claim 1, wherein the multilayer construction further comprises a substrate disposed adjacent to a major surface of the barrier layer opposite from the sealing layer, wherein the polymer layer is disposed between the substrate and the barrier layer.

6. The multilayer construction of claim 1, wherein the polymer layer is formed from one or more monomers selected from (meth)acrylates, vinyl ethers, vinyl naphthylene, thiols, acrylonitrile, multifunctional thiols, multifunctional allyl monomers, or multifunctional vinyl monomers.

7. The multilayer construction of claim 1, wherein the polymer layer further comprises a plurality of nanoparticles.

8. The multilayer construction of claim 5, wherein the substrate comprises a visible light-transmissive support.

9. The multilayer construction of claim 5, wherein the substrate comprises a microstructured major surface or a quantum dot particle.

10. The multilayer construction of claim 5, further comprising a second barrier layer having a major surface, the second barrier layer disposed on a major surface of the substrate opposite of the barrier layer and sealing layer.

11. The multilayer construction of claim 1, wherein the sealing layer further comprises a plurality of inorganic nanoparticles.

12. The multilayer construction of claim 11, wherein the plurality of inorganic nanoparticles are functionalized with acrylate groups, vinyl groups, mercapto groups, epoxy groups, or a combination thereof.

13. The multilayer construction of claim 1, wherein the crosslinked silsesquioxane is formed from functionalized silsesquioxanes comprising acrylate groups, vinyl groups, mercapto groups, epoxy groups, or a combination thereof.

14. The multilayer construction of claim 1, further comprising an adhesive disposed on the sealing layer.

15. The multilayer construction of claim 1, further comprising a functional layer disposed on a major surface of the sealing layer, the functional layer selected from an antistatic layer, an easy-clean layer, an anti-scratch layer, an anti-reflection layer, a hardcoat layer, or a combination thereof.

16. The multilayer construction of claim 5, further comprising a functional layer disposed on a major surface of the substrate opposite to the barrier layer and sealing layer, the functional layer selected from an antistatic layer, an easy-clean layer, an anti-scratch layer, an anti-reflection layer, a hardcoat layer, or a combination thereof.

17. A device comprising the multilayer construction of claim 1, the device selected from a light generating device, a display, a solar cell, or a vacuum insulation panel.
